(19) United States
(12) Patent Application Publication
(10) Pub. No.: US 2007/0057202 A1
(43) Pub. Date: Mar. 15, 2007

(54) Method for making reproducible buried heterostructure semiconductor devices

(76) Inventors: Jintian Zhu, Palo Alto, CA (US); Gloria Emilia Hofler, Sunnyvale, CA (US)

Correspondence Address: AGILENT TECHNOLOGIES INC., INTELLECTUAL PROPERTY ADMINISTRATION,LEGAL DEPT., MS BLDG. E P.O. BOX 7599, LOVELAND, CO, 80537, US

(21) Appl. No.: 11/224,409

(22) Filed: Sep. 12, 2005

(51) Int. Cl. H01J 37/08

(52) U.S. Cl. 250/492.21

(57) ABSTRACT

A semiconductor device, such as a laser, and a method of manufacturing the semiconductor device. The semiconductor device includes a substrate, an etching stop layer disposed over the substrate, and an active region layer disposed on the etching stop layer. The active region layer is further disposed opposite the substrate.

### DESCRIPTION OF RELATED ART

The performance and yield of semiconductor devices depends on processing methods that enable the confinement of current, carriers, and photons. The performance and yield of these devices also depends on guiding radiation along specific directions within the device. Fabrication using buried heterostructure geometry combines all of these features effectively, and is thus commonly used when manufacturing high power lasers, electro-absorption modulators, and waveguides. For these devices, a mesa is defined in the structure of the device by etching once the basic active region structure is in place. The width of the mesa influences the mode, shape, and laser threshold of the laser, and is involved in determining whether the laser has a single mode operation.

The process of creating a mesa involves the use of either wet chemical etching techniques or dry chemical etching techniques, such as reactive ion etching (RIE) or inductance coupled plasma (ICP) etching. Some wet etching solutions result in the width of the mesa stripes at the center region becoming wider than the edge region and, likewise, the height at the center area may become different than the height at the edge area, typically shallower. On the other hand, if the stripe width is controlled for single mode operation at the edge of the wafer, the stripe width will be too wide at the center of the mesa, creating undesirable higher order modes during operation of the device. In contrast, dry etching can result in very uniform stripe width. However, a drawback to dry etching is that the surface of the wafer can be very rough after the etching process. Hence, whatever etching method is chosen, optimal device performance and device yield cannot be achieved.

### SUMMARY OF THE INVENTION

The present invention relates to a semiconductor device and a method of manufacturing the semiconductor device. The semiconductor device includes a substrate, an etching stop layer grown over the substrate, and an active region layer grown on the etching stop layer. The active region layer is further grown or deposited opposite the substrate, and is thus disposed opposite the substrate. The Fe doped InP layer is deposited on both sides of the mesa for current and index confinement.

### BRIEF DESCRIPTION OF THE DRAWINGS

Furthermore, the invention provides embodiments and other features and advantages in addition to or in lieu of those discussed above. Many of these features and advantages are apparent from the description below with reference to the following drawings.

FIG. 1 shows a semiconductor device with an etching stop layer according to an exemplary embodiment in accordance with the invention;

FIG. 2 shows the semiconductor device of FIG. 1 after a dielectric stripe is placed on the semiconductor device according to an exemplary embodiment in accordance with the invention;

FIG. 3 shows the semiconductor device of FIG. 2 after etching according to an exemplary embodiment in accordance with the invention;

FIG. 4 shows the semiconductor device of FIG. 3 after a second etching step according to an exemplary embodiment in accordance with the invention;

FIG. 5 shows the semiconductor device of FIG. 4 after adjusting the width of the mesa according to an exemplary embodiment in accordance with the invention;

FIG. 6 shows the semiconductor device of FIG. 5 after depositing a current blocking layer according to an exemplary embodiment in accordance with the invention; and

FIG. 7 shows the semiconductor device of FIG. 6 after depositing a top p-cladding layer and a contact layer according to an exemplary embodiment in accordance with the invention.

### DETAILED DESCRIPTION OF THE EXEMPLARY EMBODIMENTS OF THE INVENTION

Embodiments in accordance with the invention provide for a semiconductor device with an etching stop layer. The stop layer allows buried heterostructure semiconductor devices to be built reliably and consistently with a high yield.

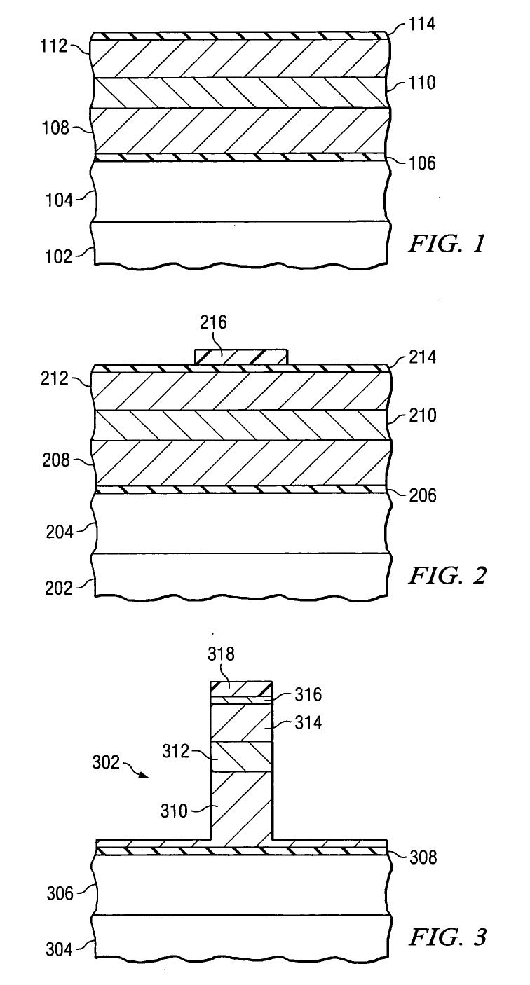

FIG. 1 shows a semiconductor device with an etching stop layer according to an exemplary embodiment in accordance with the invention. FIG. 1 shows the basic layer structure of semiconductor device 100 before the formation of a mesa. The construction of semiconductor device 100 may be considered the first step in building an exemplary embodiment of a completed semiconductor device, such as a laser, waveguide, or electro-absorption modulator. In this exemplary embodiment, semiconductor device 100 is built on substrate 102. Substrate 102 in this exemplary embodiment is InP.

Optionally, buffer layer 104 is deposited and disposed on the substrate. In this exemplary embodiment, buffer layer 104 is made from n type InP. Buffer layer 104 minimizes the defect density in substrate 102. Buffer layer 104 is typically about 1.5 μm thick.

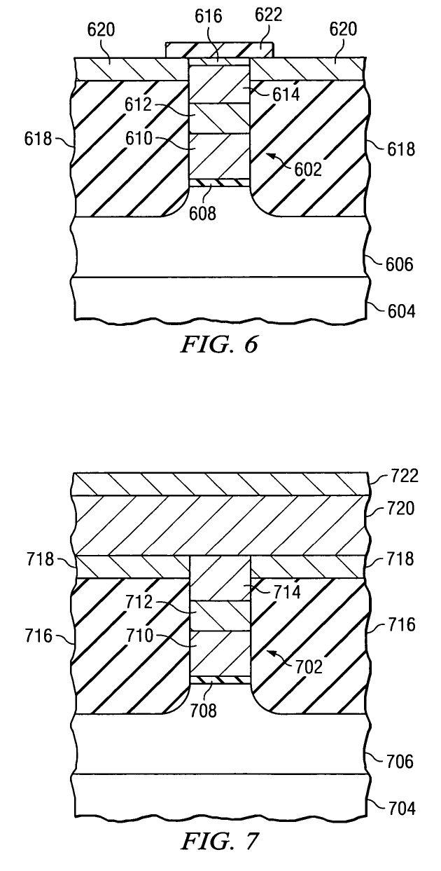

Etching stop layer 106 is deposited and disposed on buffer layer 104, or may be deposited directly on substrate 102. Etching stop layer 106 is made of materials resistant to etching processes. Etch-resistant materials suitable for use in etching stop layer 106 include InGaAsP and InGaAs. Etching stop layer 106 in the exemplary embodiment is disposed between active region layer 110 and buffer layer 104 or substrate 102. Etching stop layer 106 in the exemplary embodiment is also very thin, such as about 10 nm. The thickness of etching stop layer 106 may vary between about 5 nm and 20 nm, in order to minimize problems with light propagation in the waveguide. The separation between etching stop layer 106 and active region layer 110 is determined by dielectric stripe width 216, as shown in FIG. 2, and on the thickness of current blocking layer 618, as shown in FIG. 6. For high-speed devices, etching stop layer 106 is about 1.5 μm below active region layer 110 and the photolithographic mask width, the area occupied by layers 618 and 620 shown in FIG. 6, is about 3 μm in order to yield a mesa width of approximately 1.5 μm. The spacing between etching stop layer 106 and active region layer 110 may vary between about 1 μm and about 2 μm and the mask width may vary between about 3.5 μm and about 2.5 μm.

Deposited and disposed above etching stop layer 106 is n-cladding layer 108. N-cladding layer 108 in the exemplary embodiment is made from n type InP.

Deposited and disposed above n-cladding layer 108 is active region layer 110. Active region layer 110 may be formed from a plurality of sub-layers, each comprising different materials. In the exemplary embodiment, active region layer 110 forms a laser or waveguide, though active region layer could form any of a number of semiconductor devices. Materials suitable for use in active region layer 110 include InP, InGaAs, InGaAsP, InAlAs, AlInGaAs, and multi-layers made up from these materials.

Deposited and disposed above active region layer 110 is p-cladding layer 112. P-cladding layer 112 is made from a p-type material. A p-type material is the type of conduction material used to form a PN junction. In the exemplary embodiment, p-cladding layer 112 is made from Zn doped InP.

Deposited and disposed above p-cladding layer 112 is surface freshening layer 114. This layer has the dual purpose of defining the mesa etch profile and providing a fresh surface for regrowth of additional layers. In the exemplary embodiment, surface freshening layer 114 is made from InGaAsP, though surface freshening layer 114 may also be made from materials such as InGaAs. Surface freshening layer 114 will be removed just before p-cladding layer 720, shown in FIG. 7, is grown. Surface freshening layer 114 is removed to avoid the surface from becoming contaminated.

In semiconductor device 100, the various layers are disposed relative to substrate 102. Thus, for example, etching stop layer 106 is disposed over substrate 102. Similarly, active region layer 110 is disposed over etching stop layer 106 and is disposed over substrate 102. For this reason, active region layer 110 may be characterized as disposed over etching stop layer 106 and opposite substrate 102. The other layers, such as layers 104, 106, 108, 110, 112, and 114, may be similarly characterized in terms of location relative to substrate 102. Thus, for example, once p-cladding layer 112 is added, p-cladding layer 112 may be characterized as over active region layer 110 and disposed opposite substrate 102 and etching stop layer 106.

Each of the layers shown in FIG. 1, including layers 102, 104, 106, 108, 110, 112, and 114, may be built-up on substrate 102 using a variety of techniques. For example, metalorganic vapor phase epitaxy (MOVPE) or vapor phase epitaxy (VPE) may be used to build up the layers. Other techniques may be used according to the suitability or desirability of the deposition technique.

FIG. 2 shows the semiconductor device of FIG. 1 after dielectric stripe 216 is placed on semiconductor device 100 according to an exemplary embodiment in accordance with the invention. Thus, FIG. 2 shows a second step in preparing semiconductor device 200 to form an exemplary embodiment of a completed device. Semiconductor device 200 is formed using semiconductor device 100 shown in FIG. 1. Accordingly, referring to FIG. 1 and FIG. 2, semiconductor device 100 corresponds to semiconductor device 200, substrate 202 corresponds to substrate 102, buffer layer 204 corresponds to buffer layer 104, etching stop layer 206 corresponds to etching stop layer 106, n-cladding layer 208 corresponds to n-cladding layer 108, active region layer 210 corresponds to active region layer 110, p-cladding layer 212 corresponds to p-cladding layer 112, and surface freshening layer 214 corresponds to surface freshening layer 114.

Dielectric stripe 216 is added to top of surface freshening layer 214. Dielectric stripe 216 is used to define the mesa width. Dielectric stripe 216 in the exemplary embodiment is made from SiNx or SiO2. The thickness of dielectric stripe 216 is about 500 nm, but may vary between about 450 nm and about 550 nm.

FIG. 3 shows the semiconductor device of FIG. 2 after etching according to an exemplary embodiment in accordance with the invention. Thus, FIG. 3 shows a third step in preparing semiconductor device 300 to form an exemplary embodiment of a completed device. Semiconductor device 300 is formed using semiconductor device 200 shown in FIG. 2. Accordingly, referring to FIG. 2 and FIG. 3, substrate 304 corresponds to substrate 202, buffer layer 306 corresponds to buffer layer 204, etching stop layer 308 corresponds to etching stop layer 206, n-cladding layer 310 corresponds to n-cladding layer 208, active region layer 312 corresponds to active region layer 210, p-cladding layer 314 corresponds to p-cladding layer 212, surface freshening layer 316 corresponds to surface freshening layer 214, and dielectric stripe 318 corresponds to dielectric stripe 216.

In the exemplary embodiment shown, FIG. 3, reactive ion etching, inductance coupled plasma etching, or other dry etching technique is used to etch away the unmasked or unpatterned portions of layers 316, 314, 312, and the bulk of layer 310 to just above etching stop layer 308. As a result, mesa 302 is formed. Mesa 302 allows the laser or waveguide to operate in single mode operation. The use of dry etching techniques generates a very uniform width for mesa 302.

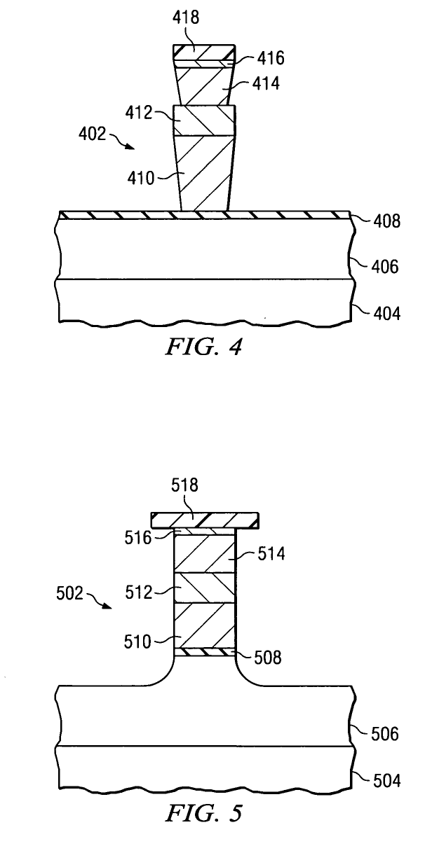

FIG. 4 shows the semiconductor device of FIG. 3 after a second etching step according to an exemplary embodiment in accordance with the invention. Thus, FIG. 3 shows a fourth step in preparing semiconductor device 400 to form an exemplary embodiment of a completed device. Semiconductor device 400 is formed using semiconductor device 300 shown in FIG. 3. Accordingly, referring to FIG. 3 and FIG. 4, mesa 402 corresponds to mesa 302, substrate 404 corresponds to substrate 304, buffer layer 406 corresponds to buffer layer 306, etching stop layer 408 corresponds to etching stop layer 308, n-cladding layer 410 corresponds to n-cladding layer 310, active region layer 412 corresponds to active region layer 312, p-cladding layer 414 corresponds to p-cladding layer 314, surface freshening layer 416 corresponds to surface freshening layer 316, and dielectric stripe 418 corresponds to dielectric stripe 318.

After formation of mesa 402 using dry etching techniques, semiconductor device 400 is subjected to a selective wet etching solution. A selective wet etching solution only dissolves or attacks certain, targeted materials so that only certain layers are worn. In the exemplary embodiment, a solution of HCL and deionized water (H2O) is used with a ratio of HCL:H20=2:1 or 1:1 in order to smooth the surface on etching stop layer 408. However, other suitable solutions may be used, so long as any remaining portion of n-cladding layer 410 is removed above etching stop layer 408. This wet etching process creates a very smooth surface across the surface of etching stop layer 408. In addition, a portion of n-cladding layer 410 near etching stop layer 408 is also worn, slightly narrowing the base of n-cladding layer 410. Similarly, a portion of p-cladding layer 414 is worn near active region layer 412, slightly narrowing the base of p-cladding layer 414.

FIG. 5 shows the semiconductor device of FIG. 4 after adjusting the width of the mesa according to an exemplary embodiment in accordance with the invention. Thus, FIG. 5 shows a fifth step in preparing semiconductor device 500 to form an exemplary embodiment of a completed device. Semiconductor device 500 is formed using semiconductor device 400 shown in FIG. 4. Accordingly, referring to FIG. 4 and FIG. 5, mesa 502 corresponds to mesa 402, substrate 504 corresponds to substrate 404, buffer layer 506 corresponds to buffer layer 406, etching stop layer 508 corresponds to etching stop layer 408, n-cladding layer 510 corresponds to n-cladding layer 410, active region layer 512 corresponds to active region layer 412, p-cladding layer 514 corresponds to p-cladding layer 414, surface freshening layer 516 corresponds to surface freshening layer 416, and dielectric stripe 518 corresponds to dielectric stripe 418.

After wet etching with a selective solution, semiconductor device 500 is etched using a non-selective etching solution. A non-selective etching solution dissolves or attacks all of the materials of semiconductor device 500. In the exemplary embodiment, a solution of HBr, hydrogen peroxide (H202), and deionized water (H20) is used as the non-selective etching solution. A ratio of HBr:H202:H20=20:4:200 in order to wear a portion of all of the layers, especially from the sides of mesa 502. However, other suitable solutions may be used, so long as damage from dry etching is removed and mesa 502 sidewalls are made smooth.

As a result of the process to this point, the width of mesa 502 is carefully and reproducibly controlled in order to ultimately control the performance of the finished device. In addition, the width of mesa 502 shrinks such that dielectric stripe 518 extends over the edges of mesa 502. Because dielectric stripe 518 extends past the edges of mesa 502, dielectric stripe 518 will prevent over-shoot of a later-added current blocking layer, such as current blocking layer 618 shown in FIG. 6.

FIG. 6 shows the semiconductor device of FIG. 5 after depositing a current blocking layer according to an exemplary embodiment in accordance with the invention. Thus, FIG. 6 shows a sixth step in preparing semiconductor device 600 to form an exemplary embodiment of a completed device. Semiconductor device 600 is formed using semiconductor device 500 shown in FIG. 5. Accordingly, referring to FIG. 5 and FIG. 6, mesa 602 corresponds to mesa 502, substrate 604 corresponds to substrate 504, buffer layer 606 corresponds to buffer layer 506, etching stop layer 608 corresponds to etching stop layer 508, n-cladding layer 610 corresponds to n-cladding layer 510, active region layer 612 corresponds to active region layer 512, p-cladding layer 614 corresponds to p-cladding layer 514, surface freshening layer 616 corresponds to surface freshening layer 516, and dielectric stripe 622 corresponds to dielectric stripe 518.

After etching with a non-selective solution, current blocking layer 618 is deposited or added above buffer layer 606, and around mesa 602. In the exemplary embodiment, current blocking layer 618 is made of Fe doped InP and has a thickness of about 3 μm. Current blocking layer 618 may vary in thickness between about 2.5 μm and about 3.5 μm. Current blocking layer 618 provides current confinement at the active region.

After adding current blocking layer 618, diffusion stopping layer 620 is deposited or added above current blocking layer 618 and around mesa 602. In the exemplary embodiment, diffusion stopping layer 620 is made of Si doped InP having a thickness of about 0.4 μm. Thus, diffusion stopping layer 620 is adapted to block diffusion of Zn.

FIG. 7 shows the semiconductor device of FIG. 6 after depositing top p-cladding layer 720 and contact layer 722 according to an exemplary embodiment in accordance with the invention. Thus, FIG. 7 shows a seventh step in preparing semiconductor device 700 to form an exemplary embodiment of a completed device. Semiconductor device 700 is formed using semiconductor device 600 shown in FIG. 6. Accordingly, referring to FIG. 6 and FIG. 7, mesa 702 corresponds to mesa 602, substrate 704 corresponds to substrate 604, buffer layer 706 corresponds to buffer layer 606, etching stop layer 708 corresponds to etching stop layer 608, n-cladding layer 710 corresponds to n-cladding layer 610, active region layer 712 corresponds to active region layer 612, p-cladding layer 714 corresponds to p-cladding layer 614, current blocking layer 716 corresponds to current blocking layer 618, and diffusion stopping layer 718 corresponds to diffusion stopping layer 620.

After adding current blocking layer 716 and diffusion stopping layer 718, the dielectric stripe layer 622 in FIG. 6 is removed. In the exemplary embodiment, dielectric stripe 622 is removed with HF. Surface freshening layer 616 is removed with a solution made from H2SO4:H20:H202 in a ratio of 10:1:1. Thereafter, top p-cladding layer 720 is deposited or added over diffusion stopping layer 718 and over mesa 702. Top p-cladding layer 720 is made from Zn doped InP. Top p-cladding layer 720 is about 1.5 μm thick, though may vary in thickness from about 1 μm to about 2 μm. After top p-cladding layer 720 has been added, contact layer 722 is added or deposited over top p-cladding layer 720. Contact layer 722 may be made of Zn doped InGaAs or a variety of other materials, such as InGaAsP. Contact layer 722 is about 0.2 μm, but may vary in thickness from about 0.15 μm to about 0.25 μm.

While what has been described constitute exemplary embodiments in accordance with the invention, it should be recognized that the invention can be varied in numerous ways without departing from the scope thereof. Because embodiments in accordance with the invention can be varied in numerous ways, it should be understood that the invention should be limited only insofar as is required by the scope of the following claims.

We claim:

1. A semiconductor device comprising:
a substrate;
an etching stop layer disposed over the substrate; and
an active region layer disposed on the etching stop layer, wherein the active region layer is further disposed opposite the substrate.

2. The semiconductor device of claim 1 further comprising a p-cladding layer disposed over the active region layer, wherein the p-cladding layer is further disposed opposite the substrate and the etching stop layer.

3. The semiconductor device of claim 2 further comprising an n-cladding layer disposed over the etching stop layer, wherein the n-cladding layer is further disposed opposite the substrate.

4. The semiconductor device of claim 2 further comprising a freshening layer disposed over the p-cladding layer, wherein the freshening layer is further disposed opposite the substrate, the etching stop layer, and the n-cladding layer.

5. The semiconductor device of claim 1 wherein a distance between the etching stop layer and the active region is between about 1 μm and about 2 μm.

6. The semiconductor device of claim 1 further comprising a current blocking layer disposed over the etching stop layer and around a mesa extending from the etching stop layer.

7. The semiconductor device of claim 1 wherein a thickness of the etching stop layer is between about 5 nm and about 20 nm.

8. A method of manufacturing a semiconductor device, wherein the method comprises:
depositing an etching stop layer on a substrate; and
depositing an active region over the etching stop layer, wherein the active region is further disposed opposite the substrate.

9. The method of claim 8 further comprising the step of depositing a p-cladding layer over the active region layer, wherein the p-cladding layer is further deposited opposite the substrate and the etching stop layer.

10. The method of claim 9 further comprising the step of depositing a current blocking layer over the etching stop layer, wherein the current blocking layer is further deposited opposite the substrate and around a mesa extending from the etching stop layer.

11. The method of claim 10 further comprising the step of depositing a freshening layer over the p-cladding layer, wherein the freshening layer is further deposited opposite the substrate, the etching stop layer, and the p-cladding layer.

12. The method of claim 9 wherein the steps of depositing an active layer and an etching stop layer are performed such that a distance between the etching stop layer and the active region is between about 1 μm and about 2 μm.

13. The method of claim 11 wherein the step of depositing a p-cladding layer is performed such that a depth of the p-cladding layer is between about 3.5 μm and about 2.5 μm.

14. The method of claim 9 wherein the step of depositing an etching stop layer is performed such that a thickness of the etching stop layer is between about 5 nm and about 20 nm.

15. A method of manufacturing a semiconductor device, wherein the method comprises:
forming a semiconductor device by performing the steps of:
depositing a buffer layer on a substrate;
depositing an etching stop layer on the buffer layer;
depositing an n-cladding layer on the etching stop layer;
depositing an active layer on the n-cladding layer; and
etching the semiconductor device according to a pattern, wherein the step of etching is stopped by the etching stop layer.

16. The method of claim 15 further comprising the step of etching the semiconductor device a second time using a selective etching solution.

17. The method of claim 16 further comprising the step of etching the semiconductor device a third time using a non-selective etching solution.

18. The method of claim 17 further comprising the step of depositing a current blocking layer over the etching stop layer and opposite the substrate.

19. The method of claim 18 further comprising the step of depositing a diffusion stopping layer over the current blocking layer and opposite the substrate and the active layer.

20. The method of claim 19 further comprising the steps of:
depositing a p-cladding layer over the diffusion stopping layer opposite the substrate and the active layer; and
depositing a contact layer over the p-cladding layer opposite the substrate, active layer, and diffusion stopping layer.
